(19) United States
(12) Patent Application Publication
(10) Pub. No.: US 2015/0054535 A1
(43) Pub. Date: Feb. 26, 2015

(54) SEMICONDUCTOR TESTING APPARATUS

(71) Applicant: SHARP KABUSHIKI KAISHA, Osaka-shi, Osaka (JP)

(72) Inventor: Kohji Yoshioka, Osaka-shi (JP)

(73) Assignee: SHARP KABUSHIKI KAISHA, Osaka-shi, Osaka (JP)

(21) Appl. No.: 14/376,654

(22) PCT Filed: Jan. 30, 2013
(86) PCT No.: PCT/JP2013/051990

§ 371 Date: Aug. 5, 2014

(30) Foreign Application Priority Data
Feb. 7, 2012 (JP) 2012-024194

(51) Int. Cl. G01R 1/18; G01R 1/067; G01R 31/26; B05B 15/04

(52) U.S. Cl. CPC G01R 1/18; B05B 15/04; G01R 1/06711; G01R 31/2601
USPC 324/750.14

(57) ABSTRACT

Provided is a probing testing apparatus of a semiconductor wafer with excellent repeatability and ease of maintenance. A gas injection port supplying oxidation preventing gas for preventing oxidation of a probe needle is provided on an inner side wall of a shielding structure mounted to a wafer probing stage within a prober so as to surround an outer side surface of a wafer. By allowing an oxidation preventing gas to flow to a part of the probe needle that is brought into contact with the wafer through an outer circumference and an upper surface of the wafer, a gas atmosphere around the probe needle is maintained by the oxidation preventing gas. With this configuration, since it is unnecessary to provide a spray nozzle above a probe card, position adjustment of the nozzle accompanying replacement of the probe card is not needed. Further, regardless of a configuration of the probe card, it is possible to blow the oxidation preventing gas even in a vertical-type probe card.

### TECHNICAL FIELD

The present invention relates to a semiconductor testing apparatus, and particularly to a semiconductor testing apparatus for performing a probing test of a semiconductor wafer.

### BACKGROUND ART

A wafer test, in which a probe card is used as a jig for inspecting a semiconductor chip in a state of a wafer, is performed by bringing a probe into contact with an electrode formed on an integrated circuit.

FIG. 6 illustrates a system configuration of an apparatus performing a probing testing process of a wafer in a conventional technology. In FIG. 6, a semiconductor testing apparatus 40 includes a spray nozzle 41, a cantilever type probe card 43, to which a probe needle 42 is mounted, a wafer probing stage 45 for fixing a wafer 44, a prober 46, and a signal processing unit 47. The signal processing unit 47 generates an electric signal for inputting to an electrode pad on a chip through the probe needle 42, and determines quality of the chip by analyzing an output signal output to this electrode pad.

Here, oxidation of the probe needle 42 is prevented by blowing oxidation preventing gas (e.g., nitrogen gas) to the probe needle 42 from the spray nozzle 41.

In this way, in the conventional semiconductor testing apparatus, oxidation of a probe needle tip is prevented by blowing the oxidation preventing gas to the probe needle through the spray nozzle (see, for example, Patent Document 1 described below).

Further, in a semiconductor testing apparatus described in Patent Document 2, besides using a spray nozzle, by enclosing an entire wafer stage in a box and injecting oxidation preventing gas into this box, a purge gas atmosphere is maintained and oxidation of a probe needle tip is prevented.

On the other hand, it is difficult to utilize the configuration using this spray nozzle in a vertical-type probe card with no opening at a center. In Patent Document 3, a hollow part is provided between an upper substrate and a lower substrate of the probe card. By providing holes for causing oxidation preventing gas to pass at the upper substrate and the lower substrate, it is possible to utilize this spray nozzle even in the vertical-type probe card.

### PRIOR ART DOCUMENTS

### Patent Documents

Patent Document 1: Japanese Patent Application Publication No. H07:273157A

Patent Document 2: Japanese Patent Application Publication No. 2001-7164A

Patent Document 3: Japanese Patent Application Publication No. H11-218548A

### SUMMARY OF THE INVENTION

### Problems to be Solved by the Invention

As described above, in a case where the spray nozzle is mounted to an upper portion of the probe needle, in a probe card with no opening at the upper portion of the needle or a probe card in which a component is mounted to an upper portion of the opening, there is a problem in that it is virtually impossible to blow the oxidation preventing gas. In a case where the vertical-type probe card is used, as described in Patent Document 3, for example, it is necessary to devise a structure of the probe card and use a probe card with a special structure.

Additionally, this spray nozzle needs a plurality of paths with expansion of a needle pointing area of the probe needle, and it can be difficult to perform uniform blowing to the entire needle.

Further, depending on an arrangement of the spray nozzle, in a case of the nozzle arrangement described in Patent Document 1, for example, a clearance capable of providing the nozzle is insufficient depending on a needle length of the probe needle, and it can be difficult to perform blowing.

Moreover, in Patent Documents 1 to 3, the spray nozzle and the probe card are physically connected. Alternatively, even if the spray nozzle and the probe card are not physically connected, they have a structure requiring position adjustment of the nozzle in every replacement of the probe card. There remains a concern about repeatability.

Further, dust produced when the probe needle is brought into contact with an electrode pad is not considered, and only blowing of the oxidation preventing gas is considered. Consequently, the dust can fly, and particularly it is difficult to operate a sensing device, such as an image sensor.

In consideration of the aforementioned problems, it is an object of the present invention to provide a semiconductor testing apparatus which is capable of maintaining a gas atmosphere around a probe needle by oxidation preventing gas, and has excellent repeatability of the probe card and ease of maintenance.

### Means for Solving the Problem

The semiconductor testing apparatus according to the present invention for achieving the above-described object is a semiconductor testing apparatus performing a probing test of a semiconductor wafer, comprising:
one or more first gas injection ports, which supply gas for preventing oxidation of a probe needle; and a shielding structure, which is mounted to a wafer probing stage within a prober and surrounds an outer side surface of the wafer.

Then, the first gas injection ports are provided on an inner side wall of the shielding structure. The gas is flowed from the first gas injection ports to a part of the probe needle that is brought into contact with the wafer through an outer circumference of the wafer and an upper surface of the wafer. The gas is retained around the probe needle.

According to the semiconductor testing apparatus having the above-described characteristics, the outer side surface of the wafer is surrounded by the shielding structure, and by allowing the oxidation preventing gas to flow from the inner side of this shielding structure to the probe needle, a gas atmosphere around the probe needle is maintained by the oxidation preventing gas. With this configuration, the spray nozzle conventionally provided above the probe card is not needed, and regardless of a configuration of the probe card, it is possible to blow the oxidation preventing gas to a probe needle tip even in a vertical-type probe card having no opening at the center.

In the semiconductor testing apparatus having the above-described characteristics, it is further preferable that a second gas injection port for blowing gas for preventing oxidation of the probe needle from below be provided on an upper surface of the shielding structure. With this configuration, lateral leakage of the gas above the wafer probing stage is prevented, and the gas atmosphere around the probe needle can be maintained by the oxidation preventing gas.

It should be noted that, in the present invention, a reference in a vertical direction in a case of “upper surface” of the shielding structure or in a case where the oxidation preventing gas is blown from “below” is a reference in a protruding direction of the probe needle. In other words, a direction opposite to the protruding direction of the probe needle is an upward direction, and the same direction as the protruding direction of the probe needle is a downward direction.

In the semiconductor testing apparatus having the above-described characteristics, it is further preferable that a gas suction port for sucking dust be provided on the inner side wall of the shielding structure.

In the semiconductor testing apparatus having the above-described characteristics, it is further preferable that at least one of the first gas injection ports can be switched to the gas suction port.

By providing the gas suction port, dust, such as aluminum dust, produced when the probe needle is brought into contact with the electrode pad is sucked, and defectiveness caused by the dust can be reduced in an image sensor or the like.

The semiconductor testing apparatus having the above-described characteristics, it is further preferable that a sealing structure, which seals a space on an opposite side to a protruding direction of the probe needle on a probe card, be provided in such a manner that an opening of the probe card provided around the probe needle is closed. With this configuration, air containing oxygen is prevented from intruding from above the probe needle and from the opposite side of the protruding direction of the probe needle, and the gas atmosphere around the probe needle can be maintained by the oxidation preventing gas.

Particularly, the sealing structure can be configured to include a partition, which closes a gap between the probe card and a pogo pin ring, and a lid plate, which closes said space on the opposite side.

In the semiconductor testing apparatus having the above-described characteristics, it is further preferable that a third gas injection port for injecting gas for preventing oxidation of the probe needle be provided in the sealing structure.

By providing the third gas injection port, the space on the side opposite the protruding direction of the probe needle is filled with the oxidation preventing gas, and this oxidation preventing gas is blown uniformly through the probe card opening. Consequently, even in the case where the needle pointing area of the probe needle increases, such as a case of simultaneous measurement for plural chips, it is possible to blow uniformly to the entire needle.

The semiconductor testing apparatus according to the present invention for achieving the above-described object is a semiconductor testing apparatus performing a probing test of a semiconductor wafer, having;
a gas injection port, which supplies gas for preventing oxidation of a probe needle; and a sealing structure, which seals a space on a side opposite to a protruding direction of the probe needle on a probe card in such a manner that an opening of the probe card provided around the probe needle is closed,
wherein the gas is flowed from the gas injection port to a part of an upper surface of the wafer that is brought into contact with the probe needle through the sealing structure, and the gas is retained around the probe needle.

### Effect of the Invention

Hereinabove, according to the present invention, since it is not necessary to provide the spray nozzle at the upper portion of the probe card, position adjustment of the nozzle accompanying replacement of the probe card is not needed, and the semiconductor testing apparatus with excellent repeatability and ease of maintenance can be realized.

### BRIEF DESCRIPTION OF THE DRAWINGS

FIG. 1 is a schematic view of a side surface structure illustrating a configuration example of a semiconductor testing apparatus according to one embodiment of the present invention.

FIG. 2 is a schematic view illustrating a configuration of a shielding structure disposed on a wafer probing stage in one embodiment of the present invention.

FIGS. 3A and 3B are schematic views illustrating configurations of the shielding structure in a case of sucking dust in one embodiment of the present invention.

FIG. 4 is a schematic view of a side surface structure illustrating a configuration example of a semiconductor testing apparatus according to one embodiment of the present invention.

FIG. 5 is a schematic view of a side surface structure illustrating a configuration example of a semiconductor testing apparatus according to one embodiment of the present invention.

FIG. 6 is a schematic view of a side surface structure illustrating a configuration example of a semiconductor testing apparatus having a conventional structure.

### DESCRIPTION OF EMBODIMENT

### First Embodiment

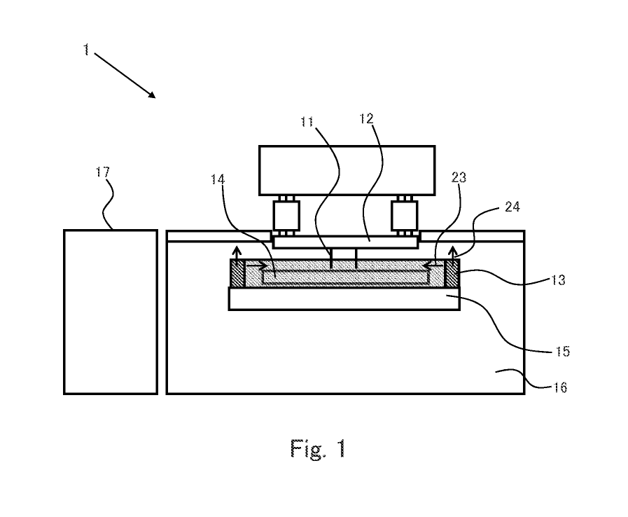

A configuration example of a semiconductor testing apparatus according to one embodiment of the present invention is illustrated in a side view of FIG. 1. A semiconductor testing apparatus 1 (appropriately referred “apparatus 1 of the present invention” hereinafter) illustrated in FIG. 1 includes a probe needle 11, a probe card 12 to which the probe needle 11 is mounted, a shielding structure 13, a wafer probing stage 15 for fixing a wafer 14, a prober 16, and a signal processing unit 17. In the present embodiment, the probe card 12 is a vertical-type probe card with no opening above the probe needle 11.

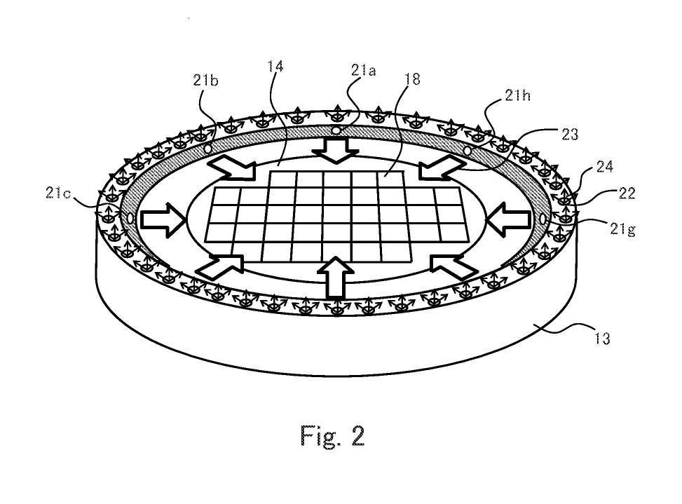

The shielding structure 13 is disposed on the wafer probing stage 15 so as to surround an outer side surface of the wafer 14. FIG. 2 illustrates a state of the wafer 14 surrounded by this shielding structure 13. First gas injection ports 21 (21a to 21h) are provided on an inner side wall of the shielding structure 13, and second gas injection ports 22 are provided at an upper surface portion thereof. It should be noted that in FIG. 2, the first gas injection ports 21d to 21f of the eight first gas injection ports 21a to 21h are not illustrated because of being hidden by the shielding structure 13.

In a probing testing process, any one of a plurality of chips 18 formed on the wafer 14 is selected, and the probe needle 11 is brought into contact with an electrode pad of this chip. An electric signal is input to the electrode pad through the probe needle 11, and quality of each chip 18 is determined by analyzing an output signal output to the electrode pad as a result of this input. The signal processing unit 17 generates this electric signal, and determines the quality of each chip 18 by analyzing this output signal. At the same time, the signal processing unit 17 performs positioning control of the wafer probing stage 15 in such a manner that the probe needle 11 is brought into contact with the electrode pad of the chip 18 of a test object. Further, the apparatus 1 of the present invention includes a device, which controls a flow rate of oxidation preventing gas supplied through the first gas injection ports 21 and the second gas injection ports 22.

From the first gas injection ports 21, an oxidation preventing gas (e.g., a nitrogen gas) 23, which prevents oxidation of the probe needle 11, is allowed to flow to a part of the probe needle 11 above the wafer 14 that is brought into contact with the wafer 14 through an outer circumference of the wafer 14 and an upper surface of the wafer. The oxidation preventing gas 23 around the probe needle is retained.

From the second gas injection ports 22, an oxidation preventing gas (e.g., a nitrogen gas) 24 for preventing oxidation of the probe needle is blown upward from below, and a wall of the oxidation preventing gas 24 is formed in a clearance space above the shielding structure 13 within the prober 16. With this configuration, lateral leakage of the oxidation preventing gases 23, 24 retained above the wafer probing stage 15 is prevented. Also, gas at an outer circumference of the wafer probing stage 15 is prevented from intruding into the space above the wafer 14 surrounded by the shielding structure 13. Consequently, a gas atmosphere around the probe needle is maintained by the oxidation preventing gas 23 or 24.

Here, the plurality of first gas injection ports 21 (eight in FIG. 2) is provided on the inner side wall surface of the shielding structure 13. However, at least one of the first gas injection ports can be used by switching to a gas suction port. By configuring in this way, dust, such as aluminum dust, produced when the probe needle is brought into contact with the electrode pad can be sucked efficiently.

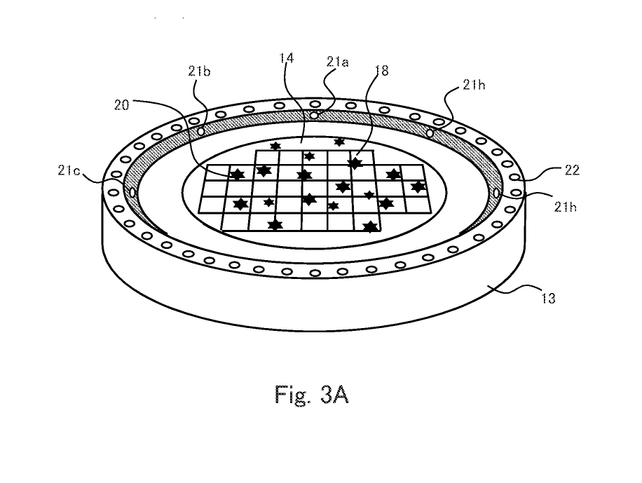

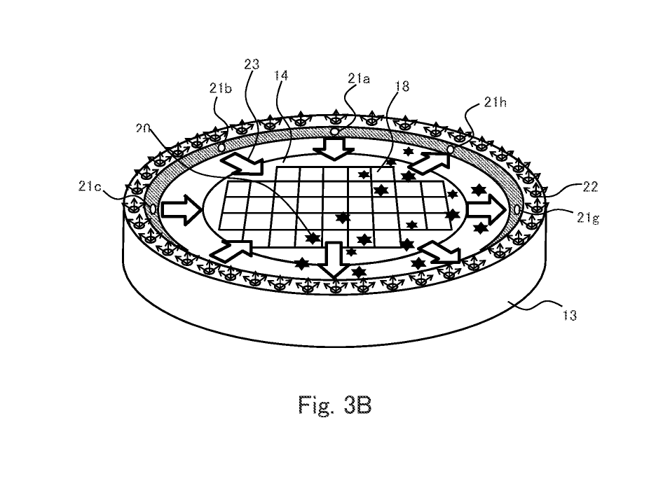

FIGS. 3A and 3B illustrate a concrete example of this dust sucking method. FIG. 3A is a state of the wafer 14 after completion of the probing test, and schematically illustrates a state in which dust 20 is scattered on the wafer 14.

In a case of removing the dust 20, for example, as illustrated in FIG. 3B, while the oxidation preventing gas 23 is blown from a half of the first gas injection ports 21 (21a to 21d), the remaining half of the first gas injection ports 21 (21e to 21h) are used by switching to gas suction ports. With this configuration, the dust existing in the scattered state on the entire wafer 14 is moved to a side where the gas suction ports 21e to 21h exist by wind pressure of the oxidation preventing gas 23, and can be removed through the gas suction ports 21e to 21h.

Since the above-described apparatus 1 of the present invention sprays the oxidation preventing gas from the first gas injection ports 21 provided on the inner side wall surface of the shielding structure 13, unlike the conventional structure where the spray nozzle for supplying the oxidation preventing gas is provided at the upper portion of the probe card 12, connection and position adjustment of the spray nozzle (the first gas injection ports 21) accompanying replacement of the probe card 12 are not needed.

Further, regardless of the structure of the probe card, the above described apparatus 1 of the present invention is capable of blowing the oxidation preventing gas to a probe needle tip, and particularly is suitable for, for example, the vertical-type probe card having no opening at the center.

### Second Embodiment

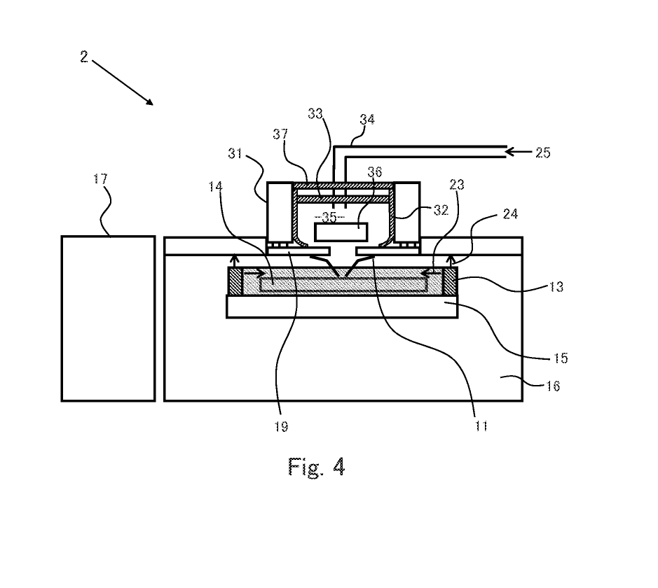

In the above-described apparatus 1 of the present invention, a case of the vertical-type probe card having no opening at the center has been described as an example. However, the present invention is not limited to this. FIG. 4 illustrates a configuration example of a case where a probe card having an opening is utilized. In addition to the respective components in the above-described apparatus 1 of the present invention, a semiconductor testing apparatus 2 (appropriately referred “apparatus 2 of the present invention” hereinafter) illustrated in a side view of FIG. 4 further includes a partition 32, which blocks a gap between a cantilever type probe card 19 and a pogo pin ring 31, a lid plate 37 which closes above a probe needle 11, an inner lid 33, and a third gas injection port 34.

The opening of the probe card 19 is closed by the partition 32, the lid plate 37, and the inner lid 33. A sealed space 35 above the probe needle 11 is separated from air outside a prober 16 containing oxygen. With this configuration, even in a case where the probe card 19 has the opening, this air does not intrude into the sealed space 35 above the probe needle 11, and the probe needle 11 can be prevented from contacting with the air.

Moreover, this sealed space 35 is filled with an oxidation preventing gas (e.g., a nitrogen gas) 25 for preventing oxidation of the probe needle through the third gas injection port 34. Since the oxidation preventing gas 25 is blown to a part of the probe needle 11 that is brought into contact with a wafer 14 through the opening of the probe card 19, a gas atmosphere around the probe needle can be maintained by the oxidation preventing gases 23 to 25.

At this time, the oxidation preventing gas 25 is blown to the opening of the probe card 19 by an almost uniform pressure. Even in a case where a needle pointing area of the probe needle increases, it is possible to blow uniformly to the entire needle.

Here, the inner lid 33 is vertically movable. The inner lid 33 sets a volume of the sealed space 35 to a minimum necessary space according to a mounting state of a component above the probe card 19, and can reduce a necessary amount of the oxidation preventing gas 25. For example, in a case of FIG. 4, a component 36 mounted above the probe card 19, such as a relay, a capacitor, a light source, a power supply module, or a substrate mounting these, is mounted. In a case of a structure without this component 36, the inner lid 33 can be moved further downward, and it is possible to attain a further energy saving operation.

It should be noted that since other configurations of the apparatus 2 of the present invention, for example, configurations of a shielding structure 13, a wafer 14, a wafer probing stage 15, a prober 16, and a signal processing unit 17 are similar to those in the aforementioned apparatus 1 of the present invention, descriptions thereof are omitted.

In the above-described apparatus 2 of the present invention, the oxidation preventing gas 25 from the third gas injection port 34 is supplied to a needle tip of the probe needle 11 through the sealed space 25, and the apparatus 2 has a separation type structure where connection of the third gas injection port 34 and the probe card 19 is not needed. Accordingly, unlike the conventional configuration, it is unnecessary to adjust a position of the spray nozzle (the third gas injection port 34) accompanying replacement of the probe card 19. The apparatus 2 of the present invention is particularly suitable for, for example, the cantilever type probe card having an opening at the center.

### Third Embodiment

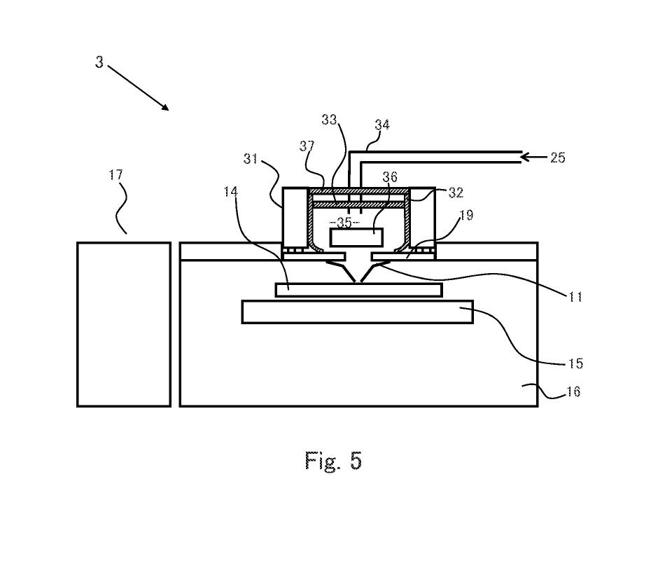

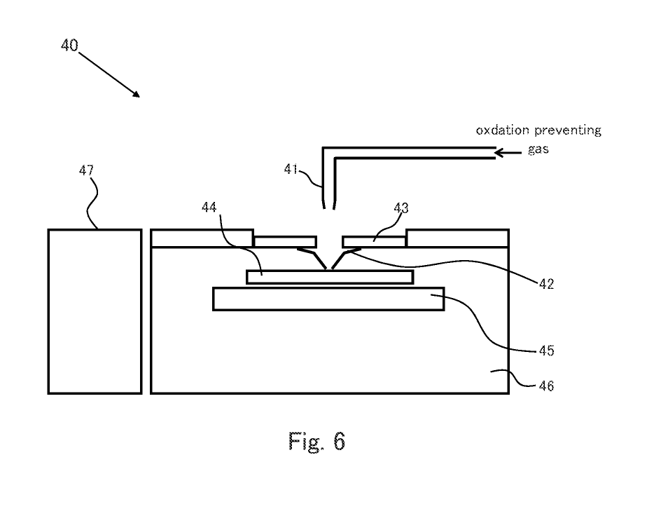

Another configuration example of a semiconductor testing apparatus according to one embodiment of the present invention is illustrated in a side view of FIG. 5. A semiconductor testing apparatus 3 (appropriately referred “apparatus 3 of the present invention” hereinafter) illustrated in FIG. 5 includes a probe needle 11, a probe card 19 to which the probe needle 11 is mounted, a wafer 14, a wafer probing stage 15, a prober 16, and a signal processing unit 17. Further, the apparatus 3 of the present invention includes a partition 32 which blocks a gap between the probe card 19 and a pogo pin ring 31, a lid plate 37 which closes above the probe needle 11, and an inner lid 33. The probe card 19, for example, is a cantilever type probe card having an opening at an upper portion of the probe needle 11.

In other words, the apparatus 3 of the present invention is a case where the aforementioned apparatus 2 of the present invention does not include a shielding structure 13. Even in this configuration, a sealed space 35 is filled with an oxidation preventing gas 25 through a third gas injection port 34. Since the oxidation preventing gas 25 is blown to a part of the probe needle 11 that is brought into contact with a wafer 14 through the opening of the probe card 19, a gas atmosphere around the probe needle can be maintained by the oxidation preventing gas 25. Further, like the apparatus 2 of the present invention, it is unnecessary to adjust a position of the spray nozzle (the third gas injection port 34) accompanying replacement of the probe card 19.

It should be noted that, in FIGS. 2, 3A and 3B, the above-described first and second embodiments are configured to include the plurality of first gas injection ports 21 (21a to 21h) provided on the inner side wall of the shielding structure 13 and the plurality of second gas injection ports 22 provided on the upper surface of the shielding structure 13, respectively. However, the present invention is not affected by the number of these gas injection ports. Further, the present invention is not limited by configurations and sizes of the first gas injection port 21 and the second gas injection port 22. For example, even in a case where the number of the first gas injection ports 21 is only one, depending on the configuration and the size of the first gas injection port 21, the oxidation preventing gas 23 is blown from this first gas injection port 21, and the gas atmosphere around the probe needle can be maintained by the oxidation preventing gas 23.

### INDUSTRIAL APPLICABILITY

The present invention can be used as the semiconductor testing apparatus, and particularly can be used for the apparatus performing the probing test of the semiconductor wafer.

### DESCRIPTION OF SYMBOLS

1 to 3 semiconductor testing apparatus according to one embodiment of the present invention (apparatus of the present invention)

11, 42 probe needle

12, 19, 43 probe card

13 shielding structure

14, 44 wafer

15, 45 wafer probing stage

16, 46 prober body

17, 47 signal processing unit

18 chip formed on wafer

20 dust

21a to 21g first gas injection port

22 second gas injection port

23 to 25 oxidation preventing gas

31 pogo pin ring

32 partition

33 inner lid

34 third gas injection port

35 sealed space sealed by partition and inner lid

36 mounted component

37 lid plate

40 semiconductor testing apparatus according to conventional art

41 spray nozzle

1. A semiconductor testing apparatus performing a probing test of a semiconductor wafer, comprising:
one or more first gas injection ports, which supply gas for preventing oxidation of a probe needle; and
a shielding structure, which is mounted to a wafer probing stage within a prober and surrounds an outer side surface of the wafer,
wherein the first gas injection ports are provided on an inner side wall of the shielding structure, and
the gas is flowed from the first gas injection ports to a part of the probe needle that is brought into contact with the wafer through an outer circumference of the wafer and an upper surface of the wafer, and the gas is retained around the probe needle.

2. The semiconductor testing apparatus according to claim 1, wherein a second gas injection port for blowing gas for preventing oxidation of the probe needle from below is provided on an upper surface of the shielding structure.

3. The semiconductor testing apparatus according to claim 1, wherein a gas suction port for sucking dust is provided on the inner side wall of the shielding structure.

4. The semiconductor testing apparatus according to claim 3, comprising a plurality of the first gas injection ports,
wherein at least one of the first gas injection ports can be switched to the gas suction port.

5. The semiconductor testing apparatus according to claim 1, wherein a sealing structure, which seals a space on an opposite side to a protruding direction of the probe needle on a probe card, is provided in such a manner that an opening of the probe card provided around the probe needle is closed.

6. The semiconductor testing apparatus according to claim 5, wherein the sealing structure is configured to include a partition, which closes a gap between the probe card and a pogo pin ring, and a lid plate, which closes said space on the opposite side.

7. The semiconductor testing apparatus according to claim 5, wherein a third gas injection port for injecting gas for preventing oxidation of the probe needle is provided in the sealing structure.
